(19) United States
(12) Patent Application Publication
(10) Pub. No.: US 2011/0038154 A1
(43) Pub. Date: Feb. 17, 2011

(54) SYSTEM AND METHODS FOR LIGHTING AND HEAT DISSIPATION

(76) Inventors: Jyotirmoy Chakravarty, Boerne, TX (US); Prashant Kumar, New Delhi (IN)

Correspondence Address: Green Star Products Inc., 175 Enterprise Parkway, Boerne, TX, 78006, US

(21) Appl. No.: 12/854,840

(22) Filed: Aug. 11, 2010

Related U.S. Application Data
(60) Provisional application No. 61/232,972, filed on Aug. 11, 2009.

(51) Int. Cl. F21S 4/00; F21V 29/00; H05K 13/00; B23P 15/26

(52) U.S. Cl. 362/249.02; 362/373; 362/294; 29/592.1; 29/890.03

(57) ABSTRACT

A system for lighting and heat dissipation of the present invention, comprises: an uni-body fixture adapted to increase a heat dissipation surface area; atleast a metal PCB housing configured to house a pluralities of LEDs with zero air-gaps; and atleast a heat pad capable of mounting the metal PCB housing at a first face, wherein a plurality of tapered and directional heat sink fins adapted longitudinally across a length of an upper face of the uni-body fixture for fastest heat dissipation from atleast a LED junctions to the atmosphere. A power supply unit having an independent heat sink surface area is adapted for heat dissipation to prevent heat contribution from the power supply unit to the light unit.

### CROSS-REFERENCE TO RELATED APPLICATION

This non-provisional patent application claims priority from the U.S. provisional patent application Ser. No. 61/232,972 filed on Aug. 11, 2010, the content of which is incorporated herein by reference.

### FIELD OF THE INVENTION

The present invention relates generally lighting devices, and more particularly, to system and methods for lighting and high efficiency heat dissipation in a low cost, convenient, environmentally safe, and cost effective manner.

### BACKGROUND OF THE INVENTION

The purpose of changing over to newer lighting technology such as high power LED lamps is to get longer life and lower power consumption for the required luminary brightness at a cost that has a reasonable payback period. High power light emitting diode (LED) technology provide all the stated benefits when tested individually, however, the key to realizing benefits from a multiple LED lamp depends upon the configuration or design of the fixture.

A key factor that impacts the operating life of a high power LED light is thermal management and dissipation. The predicted life of LED's are about 60,000 hours, however, LED's will lose their brightness and fail if the junction temperatures exceed the rated temperatures.

For the past many years the benefits of power efficiency in high power LED lights has been accepted however, the product cost has been the driving de-motivator for potential users. Further, heat dissipation and its management on the fixture level is one of the biggest challenges that the LED lighting industry faces today and its success conclusively decides the success of the product itself.

The prior art discloses different techniques for lighting and heat dissipation, for example, US Patent publication No. 20100128482 discloses a light source device having a first heat dissipation structure, an LED module, a heat energy convertor and a fan. The first heat dissipation structure includes a heat dissipation base, a first fin group attached on a top surface of the heat dissipation base. The LED module is attached on a bottom surface of the heat dissipation base of the first heat dissipation structure. The heat energy convertor is thermally connected to the heat dissipation base of the first heat dissipation structure through heat pipes, and configured for changing heat energy generated by the LED module into kinetic energy. The fan is disposed over the first fin group and driven by the heat energy convertor.

U.S. Pat. No. 7,766,513 discloses a LED lamp with a heat dissipation device. The LED lamp includes a heat sink, a triangular-shaped ridge positioned on the heat sink and an LED module mounted on the ridge. The heat sink includes a base and a plurality of first and second fins respectively extending from a first and a second surface of the base, with a plurality of channels defined between the first and second fins. The ridge is positioned on the second surface of the base. The ridge has a lateral surface which has a height decreasing from a middle to a lateral side of the ridge and decreasing from a rear end to a front end of the ridge. The LED module is mounted on the lateral surface of the ridge.

U.S. Pat. No. 6,481,874 discloses a heat dissipation system for high power LED lighting system. The high power LED lamp device includes a high power LED, a die for supplying electrical power to the LED, a heat sink secured to the die, and a housing between the heat sink and an external environment. Heat within the die is conducted to the heat sink. The housing conducts the heat received from the heat sink to the external environment.

The features of the conventional lighting and heat dissipation techniques, disclose a complex design and bulky structural indices that hinder their performance. Many such techniques are too complex for reliable operation and fail to provide efficient means to maximizing heat dissipation from the LED junction and eliminating air pockets within the fixture, which may become highly damaging to the life of the LEDs. No such system or technique is available in the commercial market at the present time which is capable of providing efficient means to maximizing heat dissipation from the LED junction and eliminating air pockets within the fixture.

In view of the disadvantages inherent in the conventional means of lighting and heat dissipation, the present scenario is necessitating the need for more practical and more efficient means for maximizing heat dissipation from the LED junction and eliminating air pockets within the fixture.

### SUMMARY FOR THE INVENTION

In view of the foregoing disadvantages inherent in the prior arts, the general purpose of the present invention is to provide an improved combination of convenience and utility, to include the advantages of the prior art, and to overcome the drawbacks inherent in the prior art. Therefore, the task of the inventions is to increase the achievable productivity and its economic efficiency.

The present invention provides an effective system and method for maximizing heat dissipation from the LED junction and eliminating air pockets within the fixture in an environmentally safe, convenient, and cost effective manner; to include advantages of the existing system and methods, and to overcome the drawbacks inherent therein.

In one aspect, a system for lighting and heat dissipation of the present invention comprises: an uni-body fixture adapted to increase a heat dissipation surface area; atleast a metal PCB housing configured to house a pluralities of LEDs with zero air-gaps; and atleast a heat pad capable of mounting the metal PCB housing at a first face, wherein a plurality of tapered and directional heat sink fins adapted longitudinally across a length of an upper face of the uni-body fixture for fastest heat dissipation from atleast a LED junctions to the atmosphere. The uni-body fixture, metal PCB housing, and the heat pad constitute a light unit for providing a uniform high intensity light. A power supply unit having an independent heat sink surface area for heat dissipation is adapted to prevent heat contribution from the power supply unit to the light unit.

In another aspect, a method for lighting and heat dissipation of the present invention comprises the steps of: forming a first heat dissipation layer; forming a second heat dissipation layer; creating zero air gap and maximum metal to metal contact for high thermal conductance; and providing a power supply unit with an independent heat sink surface area for heat dissipation separately from the light unit, wherein an uni-body fixture is adapted to increase heat dissipation surface area.

In yet another aspect, a system for lighting and heat dissipation of the present invention comprises: atleast a light unit having a plurality of LEDs mounted on atleast a first heat dissipation layer with zero air-gaps; and atleast a second heat dissipation layer adapted to house the first heat dissipation layer, wherein atleast a power supply unit is having an independent heat sink surface area for heat dissipation separately from the light unit.

Through some very unique methods, it is ensured that the junction temperature of the LEDs is kept well below its rated temperature at all times. Apart from the fact that these methods of efficient heat management help in sustaining the life of the LEDs, they also allow for the LEDs to de lit at higher currents and thereby making the lamp even more cost effective and energy efficient.

These together with other aspects of the present invention, along with the various features of novelty that characterize the invention, are pointed out with particularity in the detailed description forming a part of this disclosure. For a better understanding of the present invention, its operating advantages, and the specific objects attained by its uses, reference should be made to the accompanying drawings and descriptive matter in which, there are illustrated exemplary embodiments of the present invention.

### BRIEF DESCRIPTION OF THE DRAWINGS

The advantages and features of the present invention will become better understood with reference to the following more detailed description taken in conjunction with the accompanying drawings, in which like elements are identified with like symbols, and in which:

FIG. 1 illustrates a layer sequence of the individual components of a lighting and heat dissipation system in an exploded form, according to an exemplary embodiment of the present invention;

FIG. 2A illustrates a metal PCB housing and an array of a plurality of semiconductor light-source (LEDs) before soldering, according to an exemplary embodiment of the present invention;

FIG. 2B illustrates the plurality of semiconductor light-source (LEDs) soldered to the metal PCB housing, according to an exemplary embodiment of the present invention;

FIG. 3A illustrates an assembly of metal PCBs and heat pads onto a main aluminium uni-body just before the sheet metal cover is pressed on it, according to an exemplary embodiment of the present invention;

FIG. 3B illustrates a completed assembly of the lighting and heat dissipation system, according to an exemplary embodiment of the present invention;

FIGS. 4A and 4B illustrate a heat dissipation flow through the metal layers and along longitudinal direction of a plurality of fins, according to an exemplary embodiment of the present invention;

FIG. 5 illustrates a separation of a power supply unit with a LED unit, according to an exemplary embodiment of the present invention;

FIG. 6 illustrates a plurality of spots for temperature reading, according to an exemplary embodiment of the present invention; and

FIG. 7 illustrates a method for lighting and heat dissipation, according to an exemplary embodiment of the present invention.

Like reference numerals refer to like parts throughout several views of the drawings of the present invention.

### DETAILED DESCRIPTION OF THE INVENTION

The exemplary embodiments described herein detail for illustrative purposes are subject to many variations and structure and design. It should be emphasized, however that the present invention is not limited to a particular system and methods for lighting and high efficiency heat dissipation as shown and described. Rather, the principles of the present invention can be used with a variety of lighting and high efficiency heat dissipation configurations and structural arrangements. It is understood that various omissions, substitutions of equivalents are contemplated as circumstances may suggest or render expedient, but the present invention is intended to cover the application or implementation without departing from the spirit or scope of the it's claims.

In the following description, for purposes of explanation, numerous specific details are set forth in order to provide a thorough understanding of the present invention. It will be apparent, however, to one skilled in the art that the present invention may be practiced without these specific details.

As used herein, the term light-source' refers to any semiconductor light source including LEDs, laser diodes, quantum dots or any combination thereof, the ‘metal PCB housing’ also refers as ‘first heat dissipation layer’, the term ‘heat pad’ also refers as ‘second heat dissipation layer’ the term ‘fixture’ refers to housing or compartment, the term ‘plurality’ refers to the presence of more than one of the referenced item, and the terms ‘a’ and ‘an’ do not denote a limitation of quantity but rather denote the presence of at least one of the referenced item.

The present invention provides an effective system and method for maximizing heat dissipation from the LED junction and eliminating air pockets within the fixture in an environmentally safe, convenient, and cost effective manner; to include advantages of the existing system and methods, and to overcome the drawbacks inherent therein. The task of the inventions is to increase the achievable productivity and its economic efficiency.

According to an exemplary embodiment, the present invention provides system and methods for high power lighting and high efficiency heat dissipation. The system is capable of effectively dissipating heat from a junction of semiconductor light sources, for example light emitting diodes (also referred to as LEDs), thereby maximize the operating life of the semiconductor light sources.

A light system according to the present invention may comprise a plurality of LEDs mounted on a printed circuit board, for example, an aluminium core printed circuit board. The printed circuit board may forms a first layer of dissipation. The first layer is in turn mounted to a suitable metal surface, for example, wide aluminium uni-body surface with long heat sink fins running across its length for fastest and most effective heat dissipation.

According to an exemplary embodiment of the present invention, a base structure of the light system is capable of preventing other heat-emitting components of the light from contributing to in temperature of the LED junction. The light system of the present invention is configured for providing a highly effective thermal dissipation from LED junctions to the atmosphere through a plurality of heat sink fins. Further, the light system of the present invention is designed for low cost manufacturability that achieves uniform and highly efficient thermal dissipation.

In an exemplary embodiment, the present invention provides a high power LED lighting system that may utilizes metal lamp body thermal contact for large surface area heat sink producing even and efficient thermal dissipation and maximizes the operating life of the light emitting diodes. The light system comprises a plurality of LEDs mounted on atleast an aluminium core printed circuit board which forms the first layer of dissipation. The first layer is in turn mounted with intimate thermal contact to a larger thin aluminium plate which may be the second heat dissipation layer. The outer or the top surface of the second layer may be covered with long narrow heat sink fins. This configuration may provides a highly effective thermal dissipation from LED junctions to the first aluminium layer, which in turn transfers and dissipates the heat to the atmosphere through the carefully designed heat sink fins. The high power LED lighting system is designed for low cost manufacturability that achieves even and high efficiency thermal dissipation.

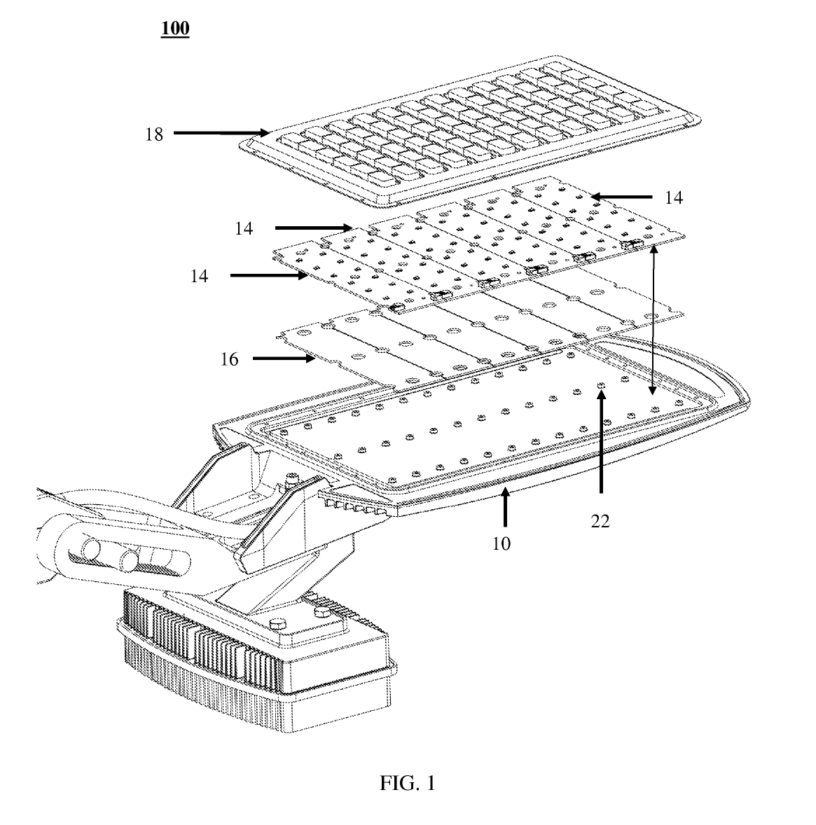

Referring to FIG. 1 which illustrates a layer sequence of the individual components of a lighting and heat dissipation system in an exploded form, according to an exemplary embodiment of the present invention. The lighting and heat dissipation system 100 comprises atleast a metal printed circuit board 14 (also referred to as ‘metal PCB’ or ‘metal PCB strip’ or ‘metal plate housing’) having atleast a LED array 12, atleast a heat pad 16 (also referred to as ‘thermal pad’) and a main uni-body 10 (also referred to as ‘uni-body construction’). The LED array 12 includes a plurality of LEDs. The uni-body construction 10 may be made of aluminium which is adapted to increase heat dissipation surface area and also to increase strength to weight ratio.

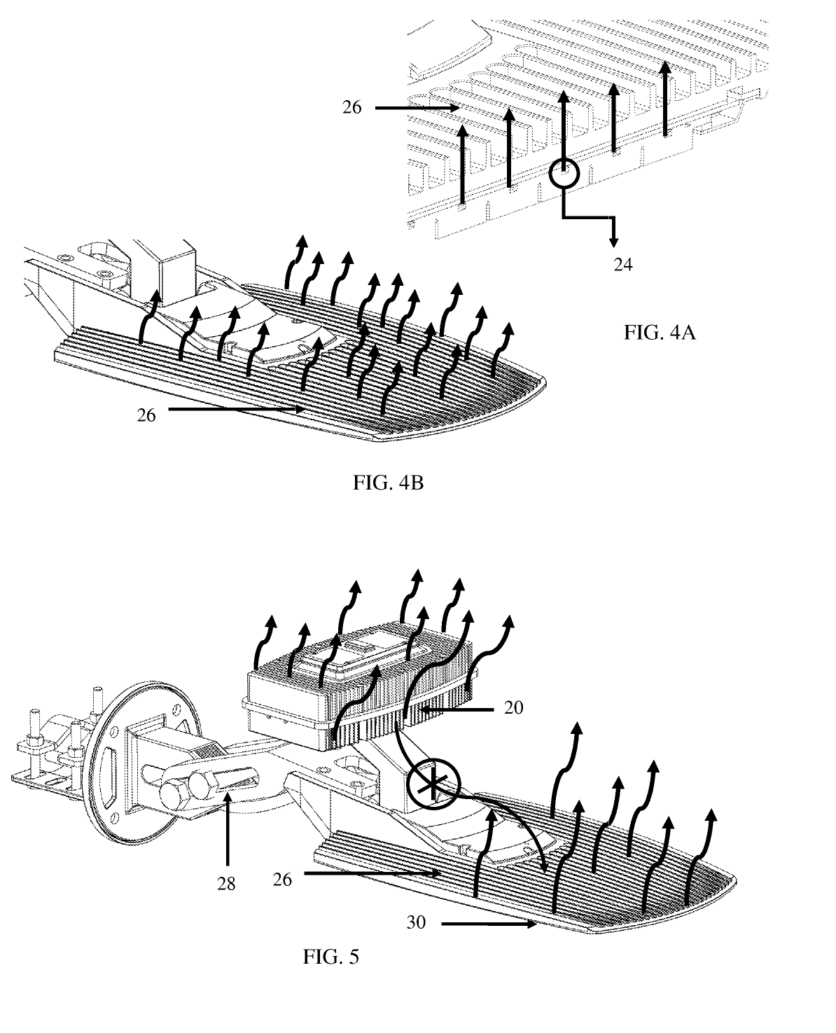

The metal PCB strips 14 may be pasted directly on the metal uni-body 10 with the help of thermally conductive heat pads 16. The heat pads 16 are adapted to further eliminate any chances of air gaps being created because of undulations in the metal surface. The heat-pads 16 may be made of a softer material with very high thermal conductivity and after a few hours of operation, become a very tough bond between the metal PCBs 14 and the uni-body 10. A cover 18 with a plurality of lens, which may be made of a sheet-metal, may be used to tightly press the entire assembly down with the use of a plurality of uniformly placed screws 22, for example thirty nine screws. This intense and uniform pressure applied on the assembly of metal PCBs 14, heat pads 16 and the uni-body 10 further ensures zero air-gap and also enhances heat transfer from the LED junction 24 (shown in FIG. 4A) to the outer surface of the uni-body 10 and then to the environment as the pressure between the two bonding surfaces is directly proportional to the amount of heat transfer from one body to other. The lens of the cover 18 may adapted to achieve uniform high intensity uniform focussed light.

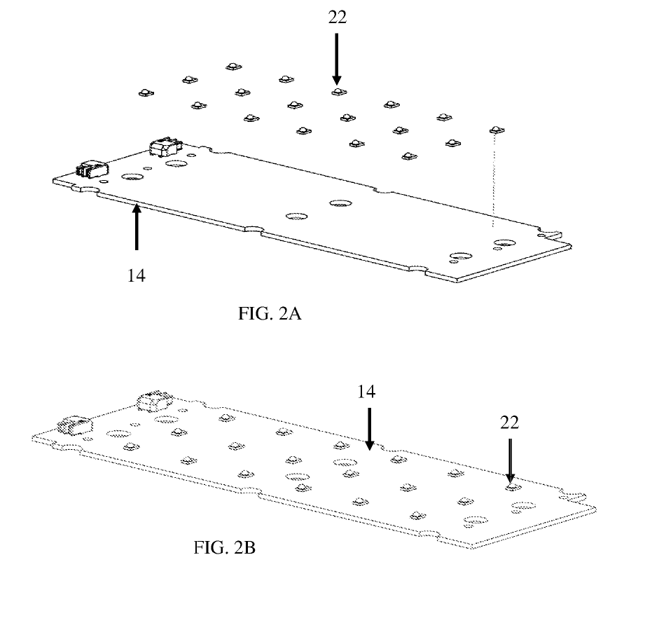

Referring to FIG. 2A which illustrates the metal PCB 14 and the LED array 12 before soldering, according to an exemplary embodiment of the present invention. The metal PCB 14 may be an aluminium plate housing which is capable of housing a plurality of LEDs 12.

Referring to FIG. 2B wherein a plurality of LEDs, for example 18 LEDs, may be directly soldered onto the metal PCB 14, according to an exemplary embodiment of the present invention. The metal PCB 14 (also referred to as ‘metal PCB housing plate’ or ‘metal plate housing’) may be made of highly conductive (thermal) aluminium and may have a larger area for heat dissipation. A plurality of different versions of the LED array 12, for example, a version of seventy two LEDs, of the light may be made of 6 such metal plate housing 14 of eighteen LEDs each. The LEDs may be soldered directly on the metal PCB 14 with zero air gaps. This may the first step of absorbing the heat generated at a very small LED junction 24 (shown in FIG. 4A) to a larger metal surface. In this case seventy two LEDs may be equally spaced and soldered to the pads 16 on six metal PCBs 14. The metal PCBs 14 are thermally conductive and made of aluminium metal.

According to an exemplary embodiment of the present invention, a plurality of LEDs, may be equally spaced and soldered to the pads 16 on metal PCBs 14. The metal PCBs 14 may be both electrically and thermally conductive. The metal PCBs 14 in turn are attached to the uni-body 10 with a larger surface area for dissipation. A layer of paste, that is electrically insulated and thermally conductive, may be applied between the metal PCBs 14 and the top plate to eliminate air gaps. The top surface of the uni-body 10 has tapered heat sink fins 26 (shown in FIGS. 4A and 4B) that are placed longitudinally. The uni-body 10 is configured to house the metal PCBs 14. The LED array 12 comprises a plurality of LEDs is mounted on the metal PCBs 14. A heat conduction flows through a plurality of metal layers and along longitudinal direction of a plurality of tapered heat sink fins 26 for even distribution and dissipation of heat. The heat flow is from the LED junctions 24 to the metal PCBs on to the uni-body 10. The tapered heat sink fins 26 on top of the uni-body 10 allow the heat to travel in the longitudinal direction for rapid and uniform dispersion to the atmosphere.

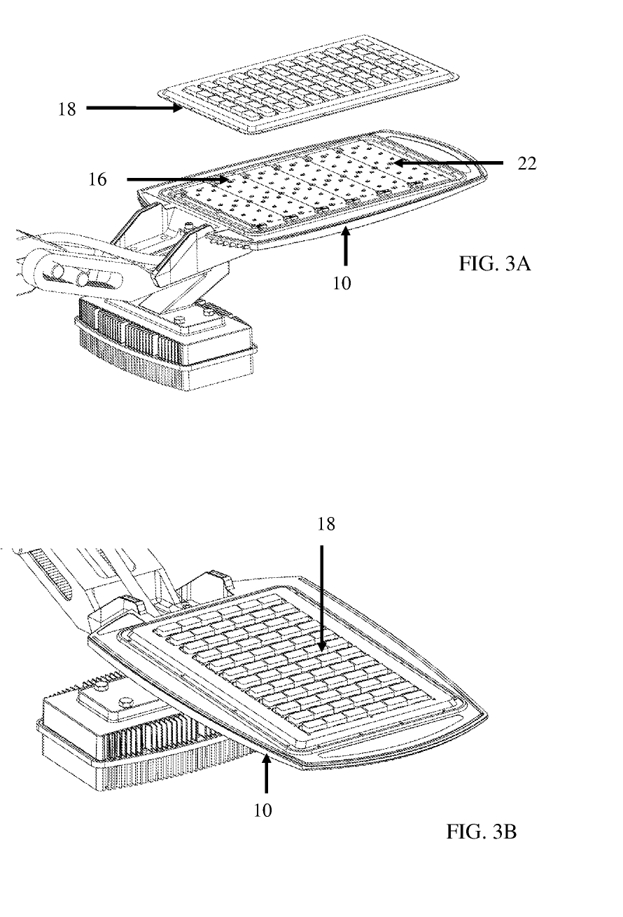

Referring to FIG. 3A which shows the assembly of a plurality of metal PCBs 14 and heat pads 16 onto the uni-body 10 just before the sheet metal cover 18 is pressed on the uni-body 10 with the help of a plurality uniformly distributed screws 22, for example, thirty nine in numbers.

Referring to FIG. 3B which illustrates completed assembly of the lighting and heat dissipation system 100, according to an exemplary embodiment of the present invention. The sheet metal cover 18 is pressed on the uni-body 10 with the help of a plurality uniformly distributed screws 22 (not shown), for example, thirty nine in numbers.

Referring to FIGS. 4A and 4B which illustrate a thermal flow pattern (heat dissipation flow) through the metal layers and along longitudinal direction of a plurality of fins 26 for even heat distribution and dissipation, according to an exemplary embodiment of the present invention. The heat flow may be from the LED junctions 24 to the metal PCBs 14 on to the plate. The plate may be made of aluminium. The fins 26 on an exposed surface of the uni-body 10 are adapted to maximize radiant thermal energy path, i.e., high conductive thermal energy travel path. The fins 26 allow the heat to travel in the longitudinal direction for rapid and uniform dispersion to the atmosphere. It can be seen over here that the distance that is required by the heat to travel from the point of its generation at the LED junction 24 to the point it dissipates into the environment is kept exceptionally low while the area of dissipation has been increased many folds for achieving fast heat dissipation. Maintaining this low junction to dissipation point distance across the entire LED array 12 (not shown) ensures uniform dissipation and uniform sustenance of LED efficacy.

Referring g to FIG. 5 which illustrates a separation of a power supply unit 20 and a LED unit 30, according to an exemplary embodiment of the present invention. The independent power supply unit 20 which is one of the biggest heat generating sources of the LED lighting system 100, may have it's own heat sink surface area and may not in anyway contribute to the junction temperature rise of the LEDs 12. The separation of the power supply unit 20 from the LED unit 30 prevents heat contribution from the power supply unit 20 to the LED unit 30. In this way heat contribution of the power supply unit 20 to the junction temperature rise of the LEDs may be eliminated. The present invention provides an easy access to power supply unit 20 for replacement and maintenance. Further, a plurality of mounting brackets 28 are adapted to allow greater than 100 degree vertical or lateral adjustment of the lighting system 100.

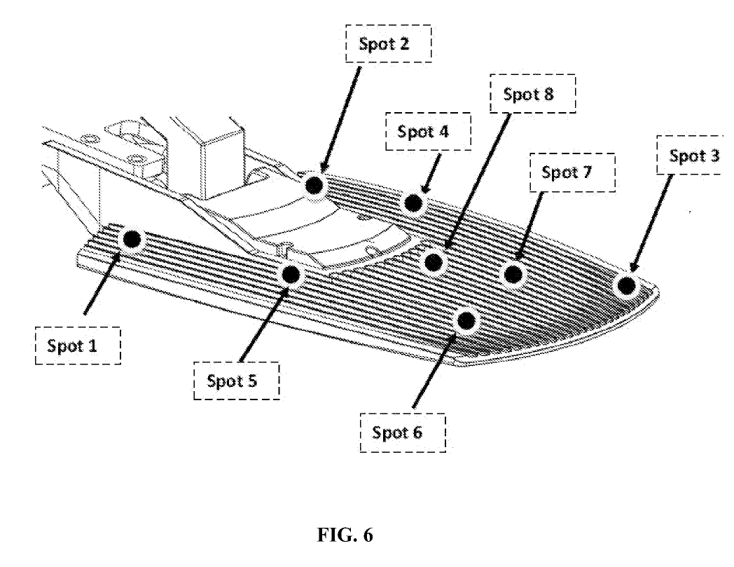

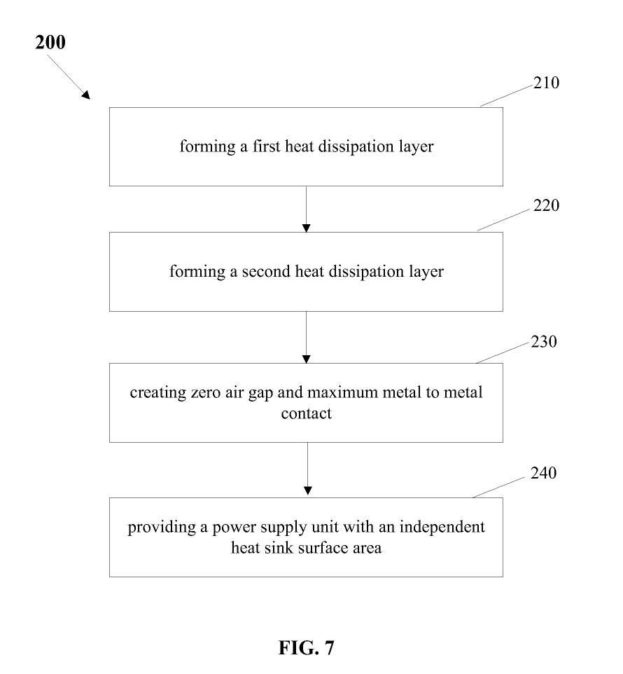

Referring g to FIG. 6 which illustrates a plurality of spots for temperature reading, according to an exemplary embodiment of the present invention.

TABLE
Temperature reading taken at the highlighted spots over a period of time.

| | Spot 1 | Spot 2 | Spot 3 | Spot 4 | Spot 5 | Spot 6 | Spot 7 | Spot 8 |
|---|---|---|---|---|---|---|---|---|
| Time | (° C.) | (° C.) | (° C.) | (° C.) | (° C.) | (° C.) | (° C.) | (° C.) |
| 17:08:51 | 67.00 | 69.50 | 75.80 | 75.30 | 71.60 | 69.80 | 74.80 | 78.40 |
| 17:20:20 | 66.10 | 68.40 | 75.20 | 74.70 | 71.30 | 69.60 | 74.80 | 76.30 |
| 17:34:50 | 65.60 | 67.80 | 74.70 | 74.10 | 70.70 | 68.90 | 73.10 | 76.10 |
| 17:50:10 | 65.20 | 67.50 | 74.40 | 73.80 | 70.40 | 68.60 | 72.90 | 75.90 |
| 18:05:40 | 65.00 | 67.30 | 74.10 | 73.40 | 70.00 | 68.20 | 73.10 | 75.70 |
| 18:21:10 | 64.50 | 66.70 | 73.70 | 73.10 | 69.70 | 67.70 | 71.80 | 75.30 |
| 18:37:30 | 64.30 | 66.40 | 73.50 | 72.90 | 69.40 | 67.50 | 71.90 | 75.20 |
| 18:50:50 | 64.50 | 66.70 | 73.60 | 73.00 | 69.50 | 67.60 | 72.90 | 75.20 |
| 19:06:10 | 64.40 | 66.40 | 73.40 | 72.90 | 69.40 | 67.50 | 73.00 | 75.10 |
| 19:21:30 | 64.00 | 66.40 | 73.30 | 72.70 | 69.30 | 67.40 | 72.20 | 75.30 |
| 19:36:50 | 64.00 | 66.40 | 73.30 | 72.80 | 69.20 | 67.20 | 72.10 | 75.20 |
| 19:51:55 | 64.40 | 68.60 | 73.40 | 72.80 | 69.30 | 67.50 | 72.50 | 74.20 |

Sampling Interval: 15 minutes;
Total Time: 2 h 43 m 5.0 s;
Ambient Temperature: 33° C.
No. of LEDs: 72;
LED Power: 170 Watt;
Total Power Usage: 200 Watt

As can be seen in the FIG. 6 and the corresponding table above that the lighting system 100 and methods of heat dissipation of the present invention ensure uniform heat dissipation. The temperature readings taken at the spots highlighted in the FIG. 6 show that the junction temperature of the LEDs is maintained well below the rated temperature of 140° C. of the LEDs used. The uniform heat dissipation is achieved by the way of the configuration and management of the present inventions. Accordingly, the present invention provides heat dissipation and its management on the fixture level. Further, in all the temperature measurements observed the difference in the junction and casing temperature in a fully loaded fixture may not exceed 3%.

Thus proving highly efficient thermal dissipation system utility. The present inventions may ensure that the LEDs last their full life of 60,000 hours thereby and are used to their fullest potential. This may not only have a huge positive impact on the energy savings but will also make LED lights less expensive and widely accepted.

According to an exemplary embodiment, the present invention provides a high power LED lighting and heat dissipation system 100 that is made for high efficiency thermal dissipation manufacturability and adaptability to multiple lighting applications. The system 100 may have a unique modular design with fewer than six modules that may be easily assembled to meet the LEDs lumen requirements and the specific lighting application.

The configuration of the lighting and heat dissipation system 100 of the present invention creates the shortest path to the environment with zero air-gap which ensures minimum heat resistance and minimum distance and transient time for heat to travel.

In an exemplary embodiment, a system for lighting and heat dissipation 100 of the present invention comprises: an uni-body fixture 10 adapted to increase a heat dissipation surface area; atleast a metal PCB housing 14 configured to house a pluralities of LEDs 12 with zero air-gaps; and atleast a heat pad 16 capable of mounting the metal PCB housing 14 at a first face, wherein a plurality of tapered and directional heat sink fins 26 adapted longitudinally across a length of an upper face of the uni-body fixture 10 for fastest heat dissipation from atleast a LED junctions 24 to the atmosphere. The uni-body fixture 10, metal PCB housing 14, and the heat pad 16 constitute a light unit 30 for providing a uniform high intensity light. A power supply unit 20 having an independent heat sink surface area for heat dissipation to prevents heat contribution from the power supply unit 20 to the light unit 30.

The uni-body fixture 10 having an housing at a lower face for retaining atleast the metal PCB housing 14, wherein the metal PCB housing 14 is capable of forming a first heat dissipation layer. A second face of the heat pad 16 is covered with the plurality of tapered and directional heat sink fins 26. The heat pad 16 is capable of forming a second heat dissipation layer 16.

In an exemplary embodiment, a system for lighting and heat dissipation 100 of the present invention comprises: atleast a light unit 30 having a plurality of LEDs 12 mounted on atleast a first heat dissipation layer with zero air-gaps; and atleast a second heat dissipation layer 16 adapted to house the first heat dissipation layer, wherein atleast a power supply unit 20 is having an independent heat sink surface area for heat dissipation separately from the light unit 30.

Referring to FIG. 7, which illustrates a method 200 for lighting and heat dissipation of the present invention, according to an exemplary embodiment of the present invention. The method 200 comprises the steps of: forming a first heat dissipation layer at a step 210; forming a second heat dissipation layer at a step 220; creating zero air gap and maximum metal to metal contact for high thermal conductance at a step 230; and providing a power supply unit 20 with an independent heat sink surface area for heat dissipation separately from the light unit 30 at a step 240, wherein an uni-body fixture 10 is adapted to increase heat dissipation surface area

According to an exemplary embodiment of the present invention, the second heat dissipation layer 16 is capable of eliminating air-gaps in a lower face of the uni-body fixture 10 and the first heat dissipation layer. The second heat dissipation layer 16 may enhances heat transfer from a junction 24 of the LED 12 to the outer surface of the uni-body fixture 10 and then to the environment.

According to an exemplary embodiment, the present invention provides for creation of zero air gap, i.e. to eliminate air gaps, and maximum metal to metal contact for high thermal conductance i.e., to provide high conductive thermal path from LED junctions 24 to atmosphere.

According to an exemplary embodiment, the present invention comprises a plurality metallic heat transfer surfaces from a small LED junction area 24 to large exposed surface area, for uniform thermal spread and dissipation. Further, all metallic surfaces may be aluminium or aluminium alloy for optimum electrical and thermal conductivity at reasonable cost. No specialized cooling or heat dissipation mechanism used.

According to an exemplary embodiment, the present invention provides a modular construction for configurability to meet a variety of different lighting requirements. The modular construction makes the present invention a low cost high efficiency assembly process. Further, the present invention also eliminates the use of expensive specialized conductive material and facilitates modular construction.

Although a particular exemplary embodiment of the invention has been disclosed in detail for illustrative purposes, it will be recognized to those skilled in the art that variations or modifications of the disclosed invention, including the rearrangement in the configurations of the parts, changes in sizes and dimensions, variances in terms of shape may be possible. Accordingly, the invention is intended to embrace all such alternatives, modifications and variations as may fall within the spirit and scope of the present invention.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is understood that various omissions, substitutions of equivalents are contemplated as circumstance may suggest or render expedient, but is intended to cover the application or implementation without departing from the spirit or scope of the claims of the present invention.

What is claimed is:

1. A system for lighting and heat dissipation, comprising:
an uni-body fixture adapted to increase a heat dissipation surface area;
atleast a metal PCB housing configured to house a pluralities of LEDs with zero air-gaps; and
atleast a heat pad capable of mounting the metal PCB housing at a first face,
wherein a plurality of tapered and directional heat sink fins adapted longitudinally across a length of an upper face of the uni-body fixture for fastest heat dissipation from atleast a LED junctions to the atmosphere,
wherein the uni-body fixture, metal PCB housing, and the heat pad constitute a light unit for providing an uniform high intensity light, wherein a power supply unit with an independent heat sink surface area for heat dissipation is adapted to prevent heat contribution from the power supply unit to the light unit.

2. The system for lighting and heat dissipation of claim 1, wherein the uni-body fixture having an housing at a lower face for retaining atleast the metal PCB housing, wherein the metal PCB housing is capable of forming a first heat dissipation layer.

3. The system for lighting and heat dissipation of claim 1, wherein a second face of the heat pad is covered with the plurality of tapered and directional heat sink fins, wherein the heat pad is capable of forming a second heat dissipation layer.

4. The system for lighting and heat dissipation of claim 1, wherein a metal cover having atleast a lens is adapted to apply uniform pressure to tightly press down an assembly of the metal PCB, the heat pads, and the uni-body fixture to ensure zero air-gap with the use of a plurality of uniformly placed screws.

5. The system for lighting and heat dissipation of claim 1, wherein atleast a mounting bracket is adapted to allow greater than 100 degree vertical or lateral adjustment of the light unit.

6. The system for lighting and heat dissipation of claim 1, wherein arrangement of uni-body fixture, metal PCB housing, LEDs, heat pads, and power supply unit creates a shortest path to the environment with zero air-gap which ensures minimum heat resistance, minimum distance and transient time for heat to travel.

7. The system for lighting and heat dissipation of claim 1, wherein a plurality metallic heat transfer surfaces are adapted from the LED junction area to large exposed surface area, for uniform thermal spread and dissipation.

8. A method for lighting and heat dissipation, comprising the steps of:
forming a first heat dissipation layer;
forming a second heat dissipation layer;
creating zero air gap and maximum metal to metal contact for high thermal conductance; and
providing a power supply unit with an independent heat sink surface area for heat dissipation separately from the light unit,
wherein an uni-body fixture is adapted to increase heat dissipation surface area.

9. The method for lighting and heat dissipation of claim 8, wherein an uni-body fixture thermal contact is adapted for large surface area heat sink for producing even thermal dissipation.

10. The method for lighting and heat dissipation of claim 8, wherein a plurality of tapered and directional heat sink fins are adapted for high conductive thermal energy travel path, wherein said heat sink fins allow the heat to travel in the longitudinal direction for rapid and uniform dispersion to the atmosphere.

11. The method for lighting and heat dissipation of claim 8, wherein the second heat dissipation layer is capable of eliminating air-gaps in a lower face of the uni-body fixture and the first heat dissipation layer, wherein the second heat dissipation layer enhances heat transfer from a junction of the LED to the outer surface of the uni-body fixture and then to the environment.

12. The method for lighting and heat dissipation of claim 8, wherein a metal cover with atleast a lens is adapted to apply uniform pressure to tightly press down an assembly of the first heat dissipation layer, the second heat dissipation layer, and the uni-body fixture to ensure zero air-gap.

13. The method for lighting and heat dissipation of claim 8, wherein a heat conduction flows through the first heat dissipation layer and the second heat dissipation layer and along longitudinal direction of the plurality of tapered and directional heat sink fins, wherein the heat flow is from a LED junctions to the first heat dissipation layer.

14. The method for lighting and heat dissipation of claim 8, wherein a distance between a heat generation point at the LED junction and a heat dissipation point is kept very low, wherein an area of heat dissipation is kept very large for achieving uniform and fast dissipation.

15. The method for lighting and heat dissipation of claim 8, wherein a junction temperature of the LEDs is maintained well below the rated temperature of 140° C. of the LEDs used.

16. The method for lighting and heat dissipation of claim 8, wherein a difference in the junction and a casing temperature in a fully loaded fixture is below 3%.

17. The method for lighting and heat dissipation of claim 8, wherein arrangement of uni-body fixture, metal PCB housing, LEDs, heat pads, and power supply unit creates a shortest path to the environment with zero air-gap which ensures minimum heat resistance, minimum distance and transient time for heat to travel.

18. A system for lighting and heat dissipation, comprising:
atleast a light unit having a plurality of LEDs mounted on atleast a first heat dissipation layer with zero air-gaps; and
atleast a second heat dissipation layer adapted to house the first heat dissipation layer,
wherein atleast a power supply unit is having an independent heat sink surface area for heat dissipation separately from the light unit,
wherein a plurality of tapered heat sink fins running longitudinally across a length of an upper face of a uni-body fixture for fastest heat dissipation from atleast a LED junctions to the atmosphere.
